(19) United States
(12) Patent Application Publication
(10) Pub. No.: US 2022/0178692 A1
(43) Pub. Date: Jun. 9, 2022

(54) SYSTEM, METHOD AND APPARATUS OF A MOTION SENSING STACK WITH A CAMERA SYSTEM

(71) Applicant: MINDMAZE HOLDING SA, Lausanne (CH)

(72) Inventor: Shashi BOBBA, Lausanne (CH)

(21) Appl. No.: 17/477,681

(22) Filed: Sep. 17, 2021

Related U.S. Application Data
(63) Continuation of application No. 16/226,949, filed on Dec. 20, 2018, now abandoned.
(60) Provisional application No. 62/609,051, filed on Dec. 21, 2017.

(51) Int. Cl. G01C 19/56; G01C 19/62

(52) U.S. Cl. CPC G01C 19/56; B81B 2201/0242; G01C 19/62

(57) ABSTRACT

Embodiments of the present disclosure are directed to various systems, methods and apparatuses of a motion sensing stack, comprising a plurality of magnetometers, with a camera. Preferably at least four magnetometers are included and at least one magnetometer is out of the plane of at least three other magnetometers. Preferably, the stack includes an 18D IMU (inertial measurement unit). Preferably, the 18D IMU features a 3D accelerometer, a 3D gyroscope and at least four 3D magnetometers. Alternatively, optionally a 9D IMU is provided, comprising a 3D accelerometer, a 3D gyroscope and one 3D magnetometer. The IMU may optionally be MEMS (microelectromechanical system) based.

### FIELD OF THE DISCLOSURE

The present disclosure, in at least some embodiments, is directed to systems, methods, and apparatuses of a motion sensing stack, and in particular, for such systems, methods, and apparatuses featuring a plurality of magnetometers and at least one camera.

### BACKGROUND

An IMU (inertial measurement unit) includes an accelerometer and a gyroscope. Such units can be used for determining the acceleration and relative location of a device containing same. However, the IMU does have drawbacks with regard to data and tracking accuracy.

Thus, a need exists for methods, apparatuses, and systems that can fuse data from a plurality of such sensors, that is able to overcome the drawbacks of an IMU.

### SUMMARY OF SOME OF THE EMBODIMENTS

Embodiments of the present disclosure include systems, methods and apparatuses of a motion sensing stack, comprising an IMU and a plurality of magnetometers, with at least one but preferably a plurality of cameras. Optionally each motion sensing stack has an associated camera.

Preferably at least four magnetometers are included and at least one magnetometer is out of the plane of at least three other magnetometers. Preferably, the motion sensing stack features a 3D accelerometer, a 3D gyroscope and at least four 3D magnetometers, configured as an 18D IMU. Alternatively, optionally a 9D IMU, comprising of a 3D accelerometer, a 3D gyroscope and one 3D magnetometer, can be grouped together with at least three 3D magnetometers. The IMU may optionally be MEMS (microelectromechanical system) based.

Unless otherwise defined, all technical and scientific terms used herein have the same meaning as commonly understood by one of ordinary skill in the art to which this disclosure belongs. The materials, methods, and examples provided herein are illustrative only and not intended to be limiting.

Various embodiments of the methods, systems and apparatuses of the present disclosure can be implemented by hardware and/or by software or a combination thereof. For example, as hardware, selected steps of methodology according to some embodiments can be implemented as a chip and/or a circuit. As software, selected steps of the methodology (e.g., according to some embodiments of the disclosure) can be implemented as a plurality of software instructions being executed by a computer (e.g., using any suitable operating system). Accordingly, in some embodiments, selected steps of methods, systems and/or apparatuses of the present disclosure can be performed by a processor (e.g., executing an application and/or a plurality of instructions).

Although embodiments of the present disclosure are described with regard to a “computer”, and/or with respect to a “computer network,” it should be noted that optionally any device featuring a processor and the ability to execute one or more instructions is within the scope of the disclosure, such as may be referred to herein as simply a computer or a computational device and which includes (but not limited to) any type of personal computer (PC), a server, a cellular telephone, an IP telephone, a smartphone, a PDA (personal digital assistant), a thin client, a mobile communication device, a smartwatch, head mounted display or other wearable that is able to communicate wired or wirelessly with a local or remote device. To this end, any two or more of such devices in communication with each other may comprise a “computer network.”

### BRIEF DESCRIPTION OF THE DRAWINGS

Embodiments of the disclosure is herein described, by way of example only, with reference to the accompanying drawings. With specific reference now to the drawings in detail, it is stressed that particulars shown are by way of example and for purposes of illustrative discussion of the various embodiments of the present disclosure only, and are presented in order to provide what is believed to be a useful and readily understood description of the principles and conceptual aspects of the various embodiments of inventions disclosed therein.

FIG. 1A shows a schematic of a non-limiting example of a modular system design containing the IMU and a plurality of distributed magnetometers along with the signal processing unit, while FIG. 1B relates to the optional geometry of placement of only the magnetometers, according to at least some embodiments and FIG. 1C shows an actual, exemplary flow;

FIG. 2 shows a non-limiting perspective view of the geometry of magnetometers placement, according to at least some embodiments;

FIG. 3 shows a non-limiting geometry for data fusion with IMU data;

FIGS. 4A and 4B highlight the practical issue of misalignment of the magnetometers;

FIG. 5A illustrates a non-limiting example of 3D system-in-package implementation of the proposed IMU stack with 4 magnetometers;

FIG. 5B illustrates a non-limiting example of 3D system-in-package implementation of the proposed IMU stack with 3 magnetometers;

FIG. 6 is a non-limiting, exemplary data fusion algorithm, according to at least some embodiments;

FIG. 7 shows a non-limiting exemplary implementation of a system as shown herein on a chip;

FIG. 8 illustrates a non-limiting example of a multi-camera system according to at least some embodiments of the present invention; and

FIG. 9 illustrates a non-limiting example of a drone implemented with the multi-camera system of FIG. 8 according to at least some embodiments of the present invention.

### DETAILED DESCRIPTION OF SOME OF THE EMBODIMENTS

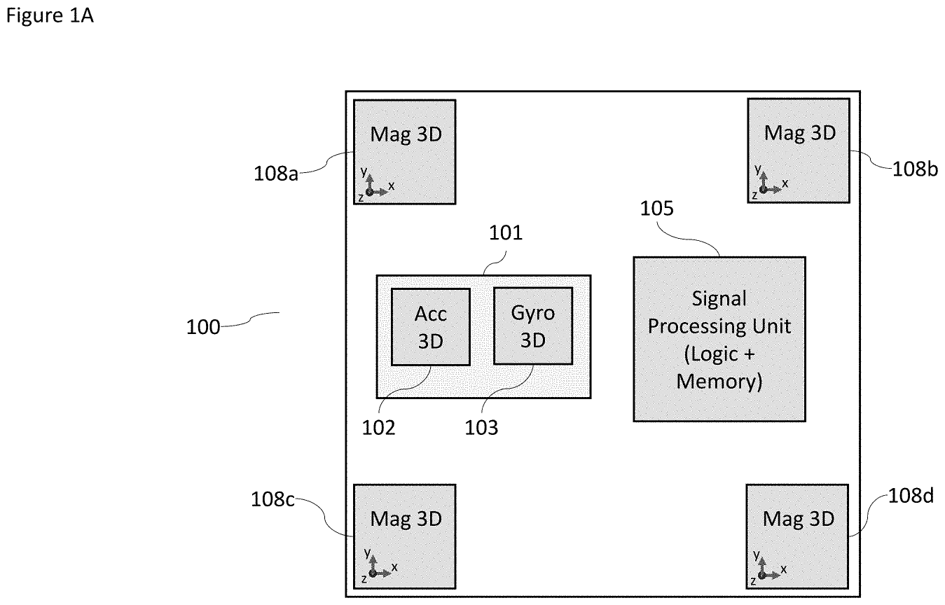

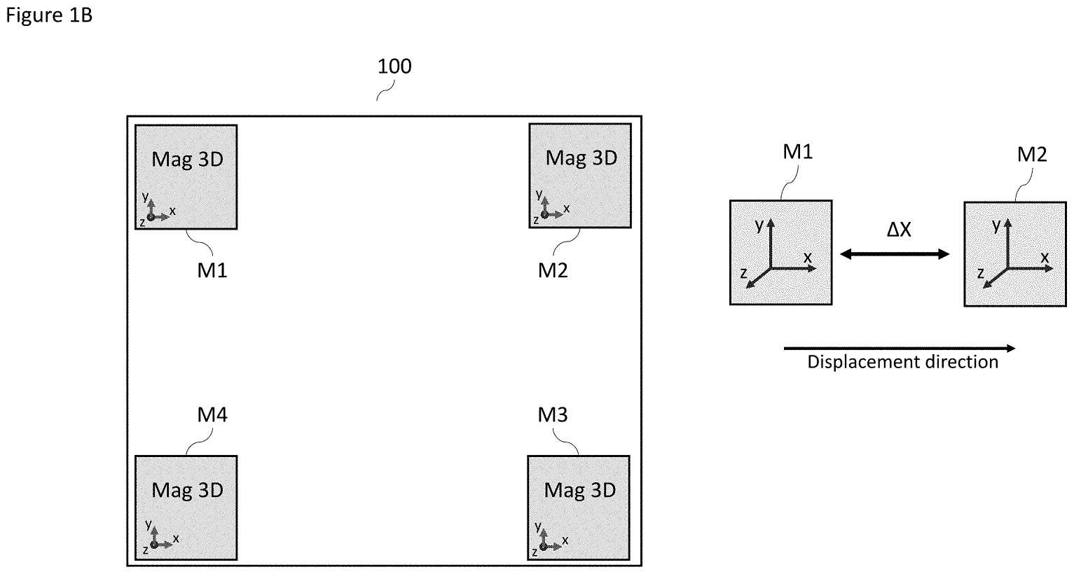

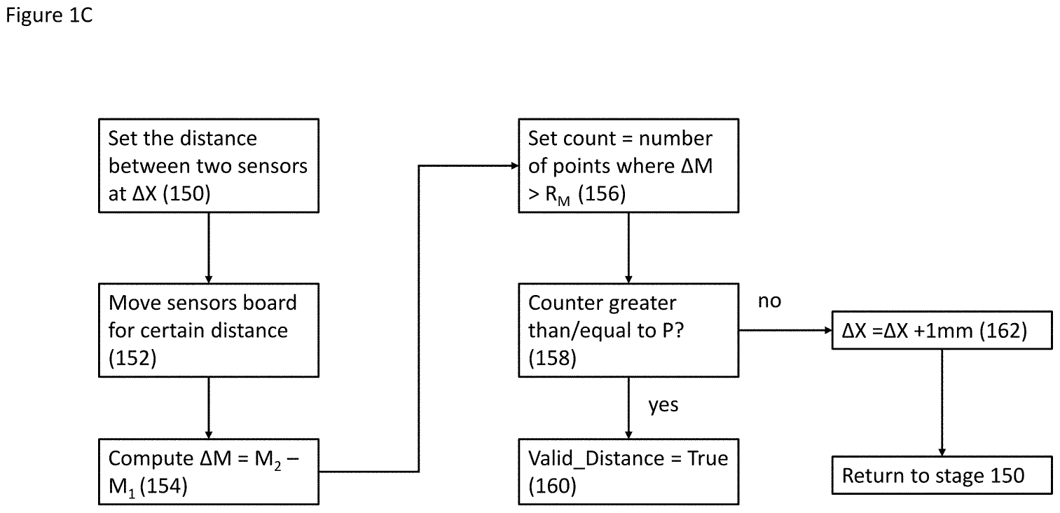

FIG. 1A shows a schematic of a non-limiting example of a modular system containing the IMU and a plurality of distributed magnetometers, according to at least some embodiments. A system (100) features a 6D IMU 101, including a 3D accelerometer (102) and a 3D gyroscope (103). System 100 includes four 3D magnetometers with high sensitivity, shown as magnetometers 108a, 108b, 108c, 108d. Preferably, no more than 3 magnetometers are in the same plane. System 100 also includes a signal processing unit 105 which will process all the data from these various sensors.

Preferably, magnetometers 108a, 108b, 108c, 108d are arranged in a triangular pyramid. The minimum bound on the slant height, with respect to the sensitivity of magnetometers 108a, 108b, 108c, 108d and also the distance between them, may optionally be determined as described with regard to FIGS. 1B and 1C.

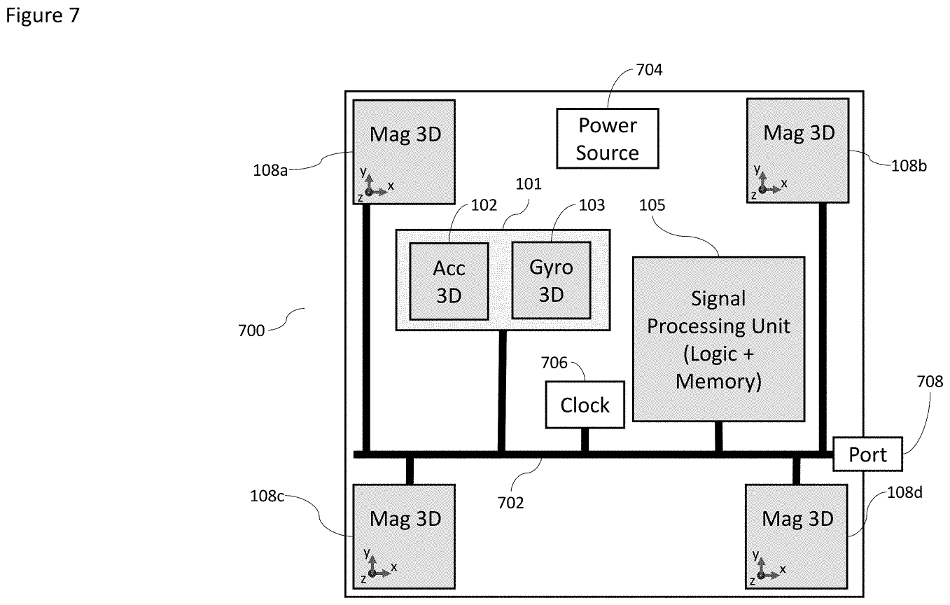

If system 100 is implemented on a chip, then preferably other components required or preferred for the operation of such a chip are included. For example and without limitation, as a chip, system 100 would preferably include a power source, a bus and the like, as shown in a non-limiting implementation in FIG. 7.

FIG. 1B relates to the preferred minimum distance between two magnetometers. A non-limiting example of a way to determine the preferred minimum distance is as follows. For two magnetometers with resolution R_{M}, do the following steps (actual flow shown in FIG. 1C):

Valid_Distance=False, ΔX=some number, such as 5 mm

while not Valid_Distance:

1. Set the distance between two sensors at ΔX (stage 150)

2. Repeat a certain number of times, say 50 times, every certain period of time, say 2 seconds (the end of which repetitions is determined with regard to stage 156):
i. Move sensors board in X direction for a certain distance, say 5 mm (stage 152)
ii. Compute ΔM=M₂−M₁ (stage 154)

3. count=number of points where ΔM>R_{M} (stage 156)

4. If count greater than or equal to a certain number (P), say 40, as considered with regard to stage 158, Valid_Distance=True (stage 160)

Else: ΔX=ΔX+1 mm (stage 162) and the process then returns to stage 150

The distribution of magnetometers 108a, 108b, 108c, 108d (shown in FIG. 1B as M1, M2, M3 and M4) is preferably such that an optimal geometry is determined for providing tracking data.

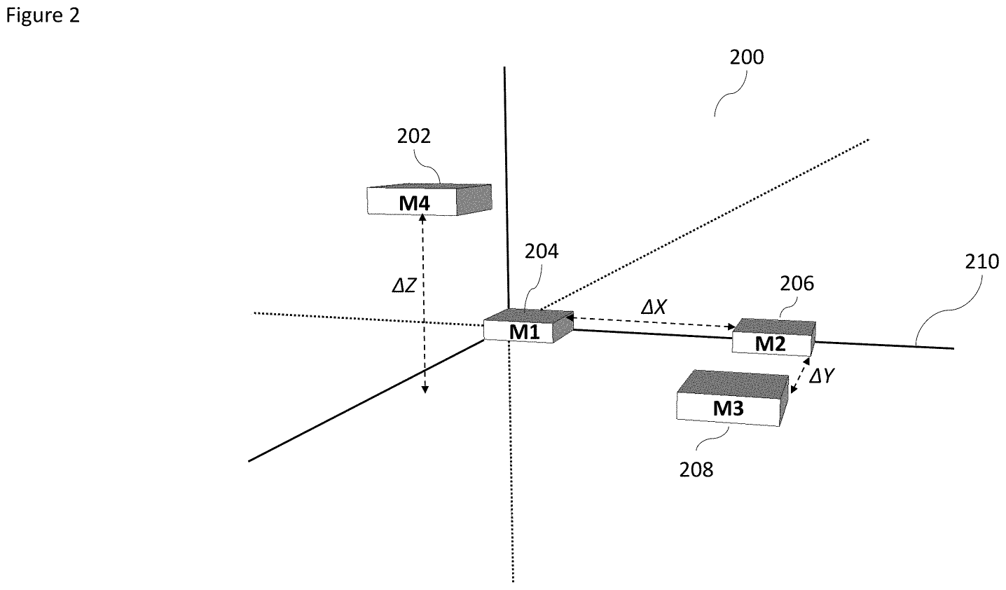

FIG. 2 shows a non-limiting perspective view of the geometry of magnetometers placement, according to at least some embodiments. Magnetometers are shown displaced in 3D space, with minimum bound on ΔX, ΔY, and ΔZ. A magnetometer apparatus 200 is shown as comprising four magnetometers 202, 204, 206 and 208. A plane 210 is explicitly shown, which could for example optionally comprise one of the dies (with MEMS components) stacked in 3D Integrated chip.

Magnetometers 204, 206 and 208 are in the same plane, shown as plane 210. Magnetometer 202 is in a different plane, such that magnetometer 202 is not in plane 210. Because magnetometer 202 is out of plane, data obtained from magnetometer 202 enable the calculation of a differential gradient for the magnetic field in the third dimension between magnetometers 204, 206 and 208, and magnetometer 202.

It should be noted that four magnetometers placed in the same plane will also enable the calculation of a differential gradient of the magnetic field, but only in two dimensions.

However, by having the one of the magnetometers displaced in a different plane, the gradients follows a triangular pyramid, and so the gradient is calculated in all the three dimensions.

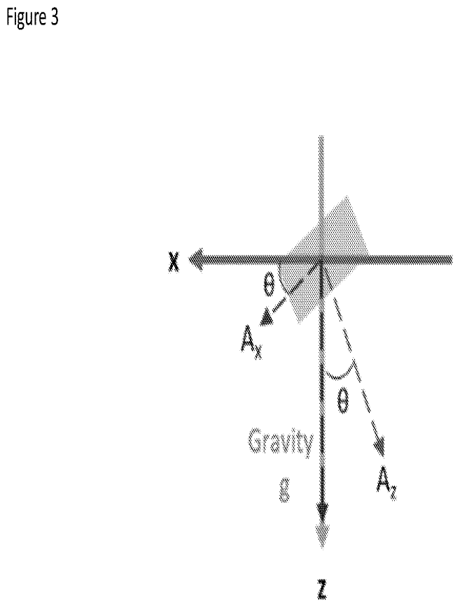

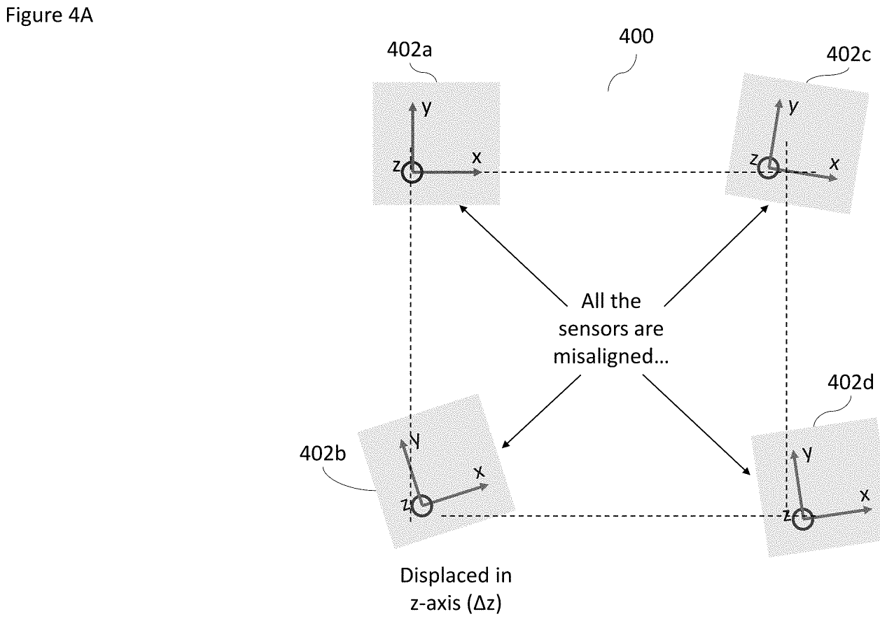

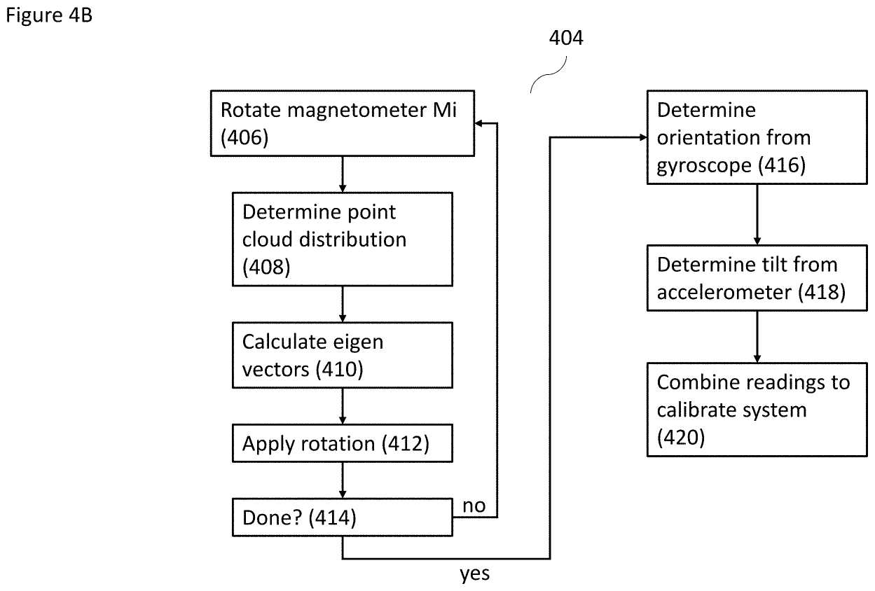

FIG. 3 shows a non-limiting geometry for data fusion with IMU data, specifically relating to accelerometer data. An exemplary data fusion algorithm is described with regard to FIG. 4 for fusing the various data points available from system 100 for example. While data fusion may optionally be used for many purposes, in the non-limiting example of FIGS. 3 and 4, it is used for tracking system 100 through a map.

For any rotation around the z-axis, the gravity vector keeps aligned with the axis, therefore providing no extra information. On top of that, in the presence of accelerations different from the gravity, the angle measurement cannot be achieved by only using accelerometer since the measure acceleration will no longer be 1g. Therefore, another source of information is required to find the exact orientation of the accelerometer to be able to remove gravitational source of acceleration from the component due to the accelerometer's movement. In order to obtain the acceleration purely due to the movement, the accelerometer reading should be rotated to the global frame of reading where it is possible to determine the effect of gravity.

FIG. 4A shows magnetometer frames which are misaligned due to mismatch during production, while FIG. 4B shows the non-limiting, exemplary data flow to compensate for such a misalignment. In a system of magnetometers 400, to compensate for the misalignment between magnetometers 402a, 402b, 402c, and 402d a calibration process is required as follows. For magnetometer i=1, 2, 3, 4 do the following (shown in the method of FIG. 4B) in a method 404:

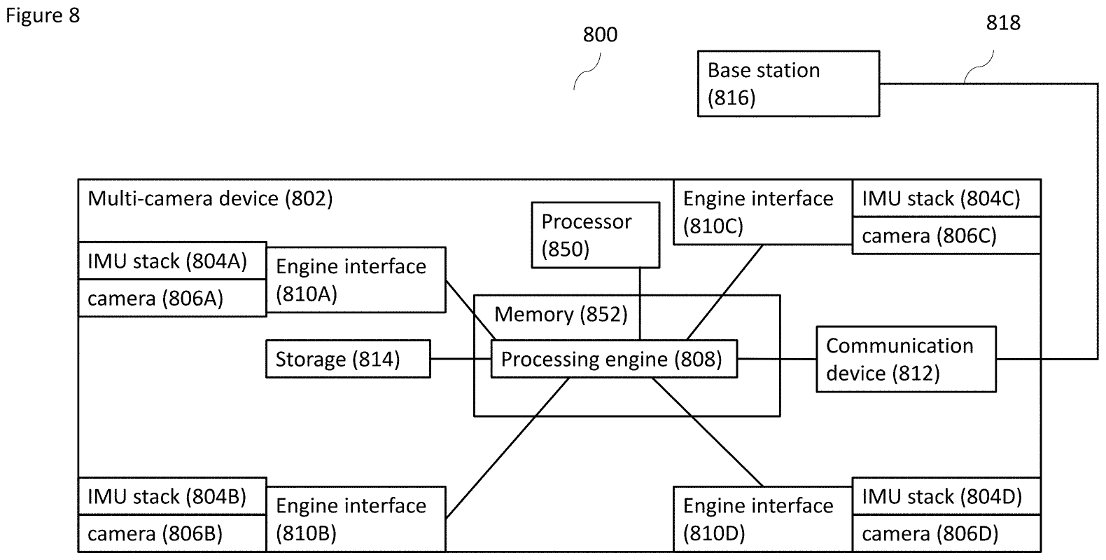

At point P rotate magnetometer Mi, for example through a figure 8 pattern, with a robotic arm (406).

Determine the point cloud distribution, Vi, for each Mi (408)

Calculate Eigen vectors of the principal directions of the point cloud distribution, Vi, for each Mi (410)

Apply the following rotation to calibrate the frame of magnetometers in 412, with regard to a selected magnetometer such as M1:

Ri=Transpose(Vi)·V1

Next it is determined whether the magnetometer Mi has been sufficiently calibrated with regard to the selected magnetometer in 414. If not, then the process preferably returns to 406 to be repeated.

The calibration process may end at 414 as the magnetometers are calibrated to each other. Optionally it continues, as shown in FIG. 4B, with further calibration with the gyroscope and the accelerometer readings also incorporated. The gyroscope is a sensor which measures the angular velocity of the body to which it is attached (by using the Coriolis Effect). It is possible to determine the sensor orientation information from a discretized sum of gyroscope's signal as follows:

$${q}_{t} = \frac{0.5}{f} ( \begin{matrix}2 & - {ω}_{t}^{x} & - {ω}_{t}^{y} & - {ω}_{t}^{z} \\ {ω}_{t}^{x} & 2 & {ω}_{t}^{z} & - {ω}_{t}^{y} \\ {ω}_{t}^{y} & - {ω}_{t}^{z} & 2 & {ω}_{t}^{x} \\ {ω}_{t}^{z} & {ω}_{t}^{y} & - {ω}_{t}^{x} & 2\end{matrix} ) {q}_{t - 1}$$

Where qₜ is the quaternion representing the rotation of the sensor with regard to a reference frame of coordination at time t and ωₜ^{x}, ωₜ^{y}, ωₜ^{z} form gyroscope 3D measurement at time t and f is sampling frequency of the device. Nonetheless, this integration introduces error in the orientation due to the existence of time variant bias on gyroscope's signal.

A magnetometer is a device capable of measuring the magnetic fields across each one of the axes of the device. In the absence of any major electromagnetic interference, the magnetic field detected by this sensor is the one coming from the earth magnetic field, which makes the magnetometer read the heading angle with respect to the magnetic north as a global reference of orientation; An important aspect about using a magnetometer, however, is its vulnerability in the presence of additional sources of electromagnetic sources, which can distort significantly the sensor's reading.

So, to improve the orientation estimation, an approach is to fuse the orientation calculated from the gyroscope with tilt estimation from accelerometer and with azimuth estimation from magnetometer, for example optionally using an optimal estimator such as a Kalman filter. The position can be obtained by a double integration of the acceleration in the global frame of navigation. However, drift occurs very quickly with (double) integration of accelerometer signals (seconds) and relatively quickly with (single) integration of gyros (minutes).

The method 404 may therefore continue with determining the orientation calculated from the gyroscope in 416. Next the tilt estimation from the accelerometer is determined in 418. The orientation and tilt information is preferably combined with the magnetometer azimuth estimation in 420, to further calibrate the system. Optionally, the method steps from 416 to 420 may also be repeated during operation of the system, as described below.

Although the IMU is prone to drift and to issues regarding the initial calibration, it does have a number of strengths that can counterbalance weaknesses of other methods. For example and without limitation, the high frequency of operation (400 Hz for example), operates without regard to external illumination conditions and provides reliable tracking in short-timespan.

Some optional uses for integrating the IMU data include finding the map scale and the gravity axis in the map coordinate system (necessary to use accelerometer data) and dead reckoning via IMU.

Map scale may optionally be recovered as follows. Optionally, an alternative system, such as an optical system, provides 3D position p_s(t) and orientation R_s(t) as functions of time t. From that, one can compute the accelerations of the camera a_s(t) by numerically deriving twice p_s with respect to t.

Assuming the IMU device and the camera sensor are placed at the same point, the optical data is related to the measured acceleration a_i(t):

a_i(t)=R_s(t)*(s*a_s(t)+g)

where g is the gravity vector expressed in m/s\hat{ }2 in the map world coordinate system, and s the map scale.

By recording optical and IMU data during a correctly tracked motion that contains acceleration, it is possible to recover g and s.

It is possible to estimate position with IMU (dead reckoning) as follows. Assume that visual tracking is accurate until time t, after which it ceases to be accurate. It is necessary to estimate position at t+d.

Rotation estimation is estimated at the last known position: A(t)=R(t)

Then one can recursively integrate rotation:

A(t+dt):=A(t)·exp(G(t)*dt)

where G(t) is a skew-symmetric matrix of gyro readings and dt is sampling period.

Then it is possible to initialize position and velocity estimates:

e(t)=p_s(t)

v(t)=(p_s(t)−p_s(t-dt))/dt

The following can then be updated:

v(t+dt):=v(t)+a_i(t+dt)*dt

p(t+dt):=p(t)+v(t+dt)*dt

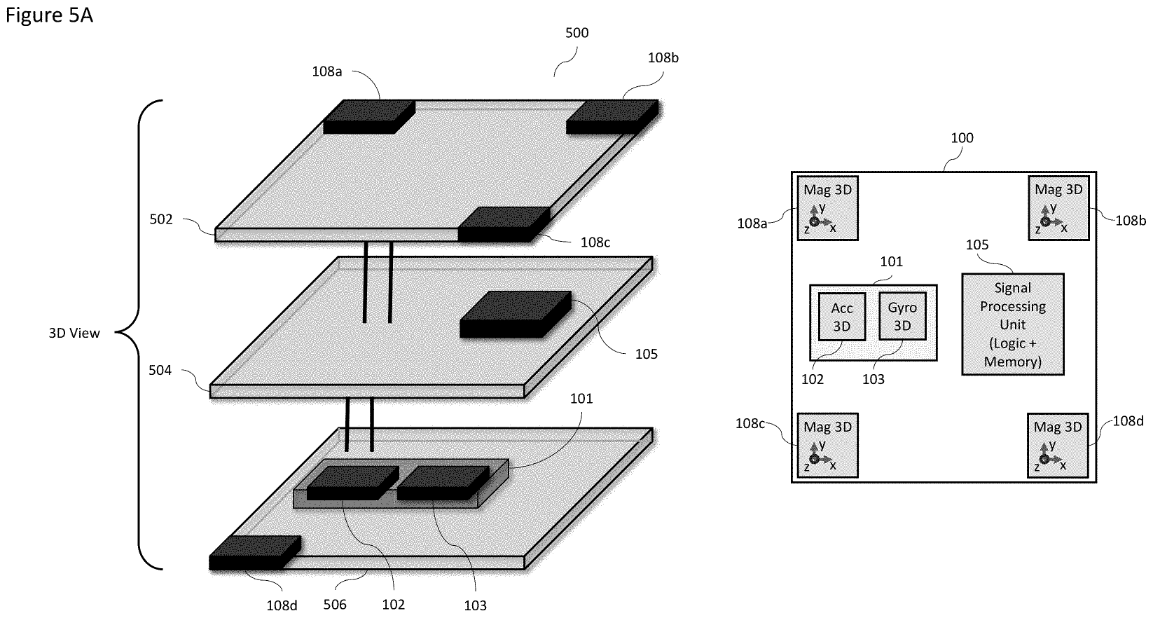

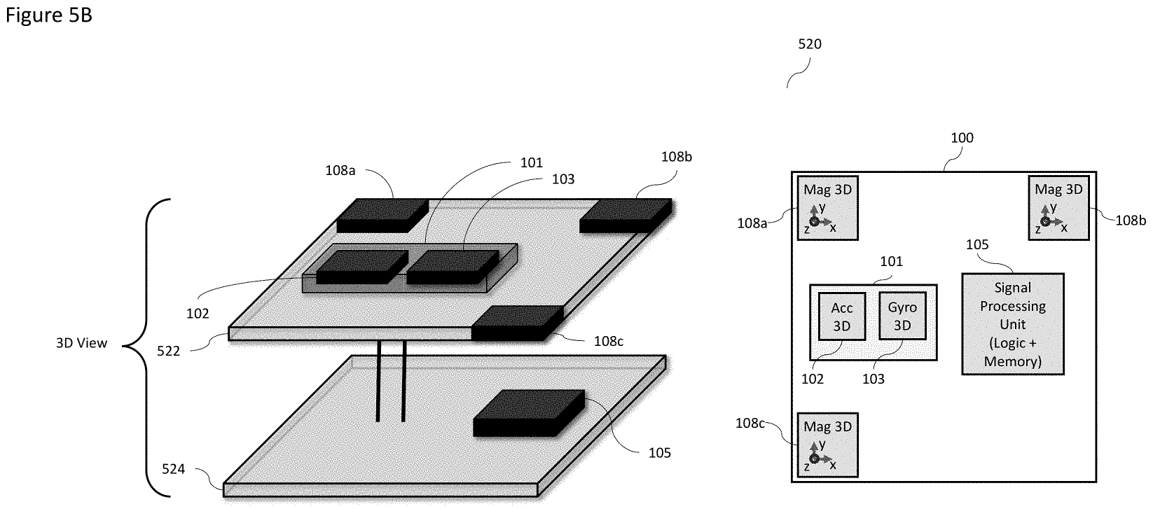

FIG. 5A illustrates a non-limiting implementation of a System-in-package of System 100, shown as a system in package 500. In order to displace one of the magnetometers in the vertical plane, optionally the system is implemented with two different dies with the MEMS components.

Die 1, MEMS1 (502) encompasses three magnetometers 108a, 108b and 108c, at the three corners of the die.

Die 2 (504) can be a standard digital IC die which preferably features a signal processing unit 105 with both Logic and memory blocks.

Die 3, MEMS2 (506) encompasses one Magnetometer 108d along with the 3D Gyroscope (102) and Accelerometer (103) in an IMU 101. Ideally the 3D magnetometer (108d) should be placed in the corner of the die which does not overlap with any Magnetometers in vertical plane of Die 1.

Preferably dies 502, 504 and 506 are interconnected through a TSV (Through Silicon Via) or a similar vertical electrical connection.

The illustration in FIG. 5A is non-limiting example for System-in-package solution for stacking dies in compact 3D packaging. However, similar block partitioning can be applied while stacking package on top of each other. An alternative extension can be stacking of PCBs on top of each other and a similar block level partitioning can be envisaged.

FIG. 5B illustrates a non-limiting example of 3D system-in-package implementation of the proposed IMU stack with 3 magnetometers. As shown, FIG. 5B illustrates a non-limiting implementation of a System-in-package of a variation on the previously described system, shown as a system in package 520, with three magnetometers. Components with the same reference numbers have the same or similar function as those described previously.

Die 1, MEMS1 (522) encompasses three magnetometers 108a, 108b and 108c, at the three corners of the die. Die 1 522 also preferably comprises the 3D Gyroscope (102) and Accelerometer (103) in an IMU 101.

Die 2 (524) can be a standard digital IC die which preferably features a signal processing unit 105 with both Logic and memory blocks.

Preferably dies 522 and 524 are interconnected through a TSV (Through Silicon Via) or a similar vertical electrical connection.

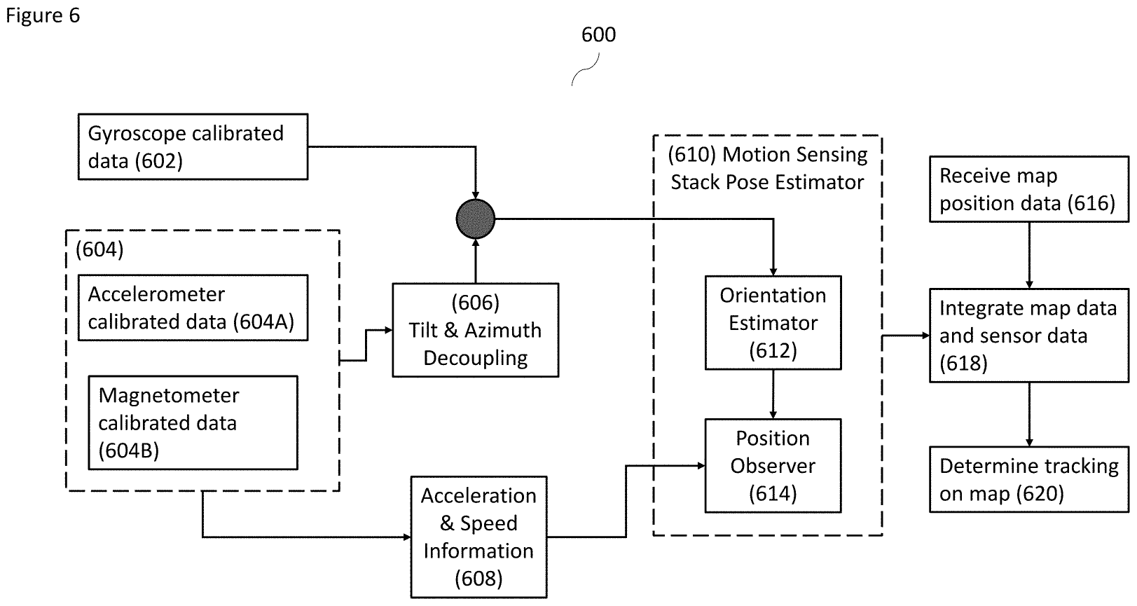

FIG. 6 is a non-limiting, exemplary data fusion process, according to at least some embodiments. As shown in a method 600, in stage 602, gyroscope calibrated data is provided. In stage 604, the orientation is estimated from accelerometer calibrated data (604A) and magnetometer calibrated data (604B). In stage 606 tilt estimation is decoupled from azimuth estimation to reduce the effect of magnetic field perturbation on accuracy of orientation

In stage 608, acceleration and speed information is received from stage 604.

In stage 610, motion sensing stack pose estimation is performed, from an orientation estimator 612 and a position observer 614. Orientation estimator 612 receives the output of stages 602 and 606. Position observer 614 receives the estimated orientation and the output of stage 608. These various types of sensor data are used to estimate the position, for example optionally using an optimal estimator such as a Kalman filter.

In stage 616, map position data is received, preferably calculated from another source of sensor data, such as optical data for example and without limitation. In stage 618, map position data and the fused sensor data are preferably integrated. Next, in stage 620, tracking of the position of the apparatus including system 100 is determined on the map, according to the integration.

FIG. 7 shows a non-limiting exemplary illustrative implementation of a system as shown herein, such as for example the system of FIG. 1A, as implemented through a chip. In this non-limiting example, the implementation is shown schematically with regard to two dimensions, although it could also be implemented three dimensionally. Components with the same reference numbers as FIG. 1A have the same or similar function. A chip 700 features the previously described components of system 100 of FIG. 1A, connected by a bus 702. Bus 702 is preferably able to handle all of the different types of traffic between the different components present on chip 700, although alternatively a plurality of busses are present (not shown). Communication through bus 702 may occur sequentially as each component sends necessary information, which is then received and acted upon by one or more additional components. Bus 702 may also be capable of multiplexed communications, or of such types of communication as time divisional multiple access, and so forth. Alternatively, the interconnection between all the hardware blocks on the chip 700 could be implemented as a network on a chip.

Chip 700 further comprises a power source 704 for providing power to the components of the chip. Power source 704 is controlled by signal processing unit 105.

A clock 706, preferably part of signal processing unit 105 or at least under the control of signal processing unit 105, provides timing functions for chip 700. To facilitate reading information from, or writing information or commands to, chip 700, preferably a port 708 is provided, to support such read/write capabilities. The interconnect delay, and thus the length and width of the interconnect (not shown), from the processing unit to all the magnetometers 108A, 108B, 108C and 108D, is preferably the same so that data is read synchronously.

FIG. 8 illustrates a non-limiting example of a multi-camera system according to at least some embodiments of the present invention. As shown, a system 800 features a multi-camera device 802, with a plurality of cameras 806, of which four are shown for the purpose of illustration only (806A, 806B, 806C and 806D). In this non-limiting example, each camera 806 is located at a separate location of multi-camera device 802 but any suitable type of place or geometry may be used. Also multi-camera device 802 may optionally have any suitable shape and is shown schematically only.

Each camera 806 preferably has a corresponding IMU stack 704, as shown for example in any of the above figures or according to any suitable implementation (such as in FIG. 1, 5A, 5B or 7 for example, with system 100 operating as an 18D IMU stack). Each IMU stack 804 features a magnetometer, and may optionally feature an accelerometer and a gyroscope. Each such component optionally features a 3D implementation as previously described, with one or more of a 3D magnetometer, a 3D gyroscope or a 3D accelerometer. Optionally each IMU stack 804 features a plurality of magnetometers, preferably four magnetometers with one out of the plane of the other three magnetometers. Optionally four magnetometers share a single accelerometer and gyroscope; or one magnetometer may optionally be associated with the accelerometer and gyroscope. In this non-limiting example, there is an IMU stack 804 for each camera 806, such that four IMU stacks 804 are shown for the purpose of illustration only (804A, 804B, 804C and 804D). Alternatively, a plurality of cameras 706 could share an IMU stack 804 (not shown).

IMU stack 804 preferably obtains measurements as described herein, which are useful for determining the location and/or orientation of camera 806, or optionally the position and orientation of the camera system 802 with respect to each of the four IMU stacks 804. Such measurements may be obtained continuously or when camera 806 is actively obtaining images. IMU stack 804 optionally includes logic as described herein for determining the location of camera 806. Alternatively, the measurements obtained by IMU stack 804 are passed to a processing engine 808, for determining the location. Optionally determining the location includes performing SLAM (simultaneous location and mapping). Each camera 806 optionally communicates with IMU stack 804, for example in regard to when camera 806 is actively obtaining images.

Each IMU stack 804 optionally has a corresponding engine interface 810 for supporting communication with processing engine 808. In this non-limiting illustration, four engine interfaces 810 are shown (810A, 810B, 810C and 810D). Engine interface 810 may optionally include any suitable hardware and/or software communication implementation. Processing engine 808 optionally determines the location and/or orientation of each camera 806, from the measurements of each IMU stack 804. Optionally processing engine 808 correlates the measurements from a plurality of IMU stacks 804 to determine location and/or orientation.

Processing engine 808 may optionally comprise suitable logic and processing functions, for example to support image capture from cameras 806 and optionally image transmission externally from device 802.

Images from cameras 806, and optionally also the previously described measurements, and/or location and/or orientation, are optionally stored in a storage 814 or communicated externally by a communication device 812. Communication device 812 may optionally feature wired or wireless communication. In this non-limiting example, communication is to a base station 816 through a communication channel 818, although optionally communication could be to any external device. Communication channel 818 is preferably wireless and may be implemented according to any suitable communication technology, including without limitation WiFi, infra-red, radio wave and cellular communication.

Multi-camera device 802 preferably features a processor 850, for example for executing instructions according to processing engine 808. As used herein, a processor generally refers to a device or combination of devices having circuitry used for implementing the communication and/or logic functions of a particular system. For example, a processor may include a digital signal processor device, a microprocessor device, and may additionally include, or be supported by, various analog-to-digital converters, digital-to-analog converters, and other support circuits and/or combinations of the foregoing. Control and signal processing functions of the system are allocated between these processing devices according to their respective capabilities. The processor may further include functionality to operate one or more software programs based on computer-executable program code thereof, which may be stored in a memory. As the phrase is used herein, the processor may be “configured to” perform a certain function in a variety of ways, including, for example, by having one or more general-purpose circuits perform the function by executing particular computer-executable program code embodied in computer-readable medium, and/or by having one or more application-specific circuits perform the function. The instructions are preferably stored in a memory 852.

Instructions may be received from base station 816 for example, and then executed by processor 850 according to the logic of processing engine 808. Images may also be passed to base station 816 from one or more cameras 806A-D, again preferably controlled by instructions executed by processor 850 according to the logic of processing engine 808.

Optionally each camera 806A-D is mounted separately on a separate gimbaled support on drone 902 that can allow each camera 806A-D to rotate 360° horizontally and up to 180° of elevation (not shown).

Optionally multi-camera device 802 is implemented with a single camera and IMU stack (not shown).

The system of FIG. 8 may be implemented with any type of motorized object, and is preferably implemented with an autonomous or remotely controlled motorized object. Non-limiting examples of such motorized objects include drones, autonomous vehicles (including without limitation cars, trucks and the like) and so forth. The components of the drone may be implemented for example as described with regard to U.S. Pat. No. 9,533,759.

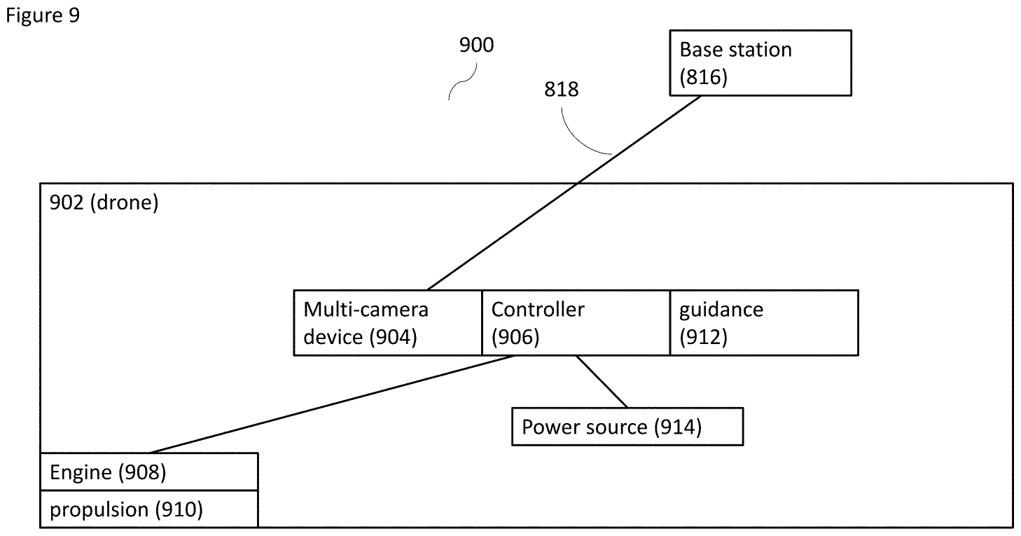

FIG. 9 shows a non-limiting, exemplary implementation of the system of FIG. 8 in a drone, with the non-limiting example of being in communication with a base station. As shown, a drone 902 features a multi-camera device 904 as previously described. Optionally the components of multi-camera device 904 are distributed over and/or throughout drone 902 (not shown). Also optionally drone 902 has a separate controller 906, which comprises a processor and memory; alternatively, controller 906 may operate according to the processor and memory of multi-camera device 904.

Controller 906 controls the functions of drone 902, for example to determine the direction and/or speed of movement of drone 902. Controller 906 controls an engine 908 which in turn power propulsion 910, to be able to determine the direction and/or speed of movement of drone 902.

In one embodiment, drone 902 can be a rotary wing aircraft. For example, drone 902 can be a multirotor helicopter, such as a quadcopter, hexacopter, or octocopter, respectively having four, six, and eight rotors. The propellers are generally directed vertically. A multiroter copter has gained in popularity as drone 902 in many applications because of its relatively simple propulsion design.

Controller 906 also receives information from, and passes information to, a guidance system 912, which may for example incorporate a SLAM (simultaneous localization and mapping) algorithm to determine the location of drone 902. As a non-limiting example, SLAM may be performed according to PCT Application No. PCT/IB18/000281, filed on 19 Jan. 2018 and owned in common with the instant application, which is hereby incorporated by reference as if fully set forth herein.

Guidance system 912 may also receive information from multi-camera device 904, such as images and information from the IMU stack, to determine the location of drone 902 and/or to provide guidance on the direction of movement for example. Such information may also be used for object or obstacle detection and/or collision avoidance, whether for an autonomous implementation or a pilot (driver) remote controlled implementation. A combination of driver remote control/autonomous control may also be implemented.

Other instruments are also optionally present and may provide data to guidance system 912, including without limitation infrared detectors, position-determining indicators, altimeters, gas detectors, global positioning systems, lasers for range detection, ultrasonic range detectors, radio position detectors, and inertial measurement units.

The communication device of multi-camera device 904 (not shown, see FIG. 8) is preferably in communication with the previously described base station 816 through the previously described communication channel 818.

Controller 906 also preferably controls a power source 914, which provides power for the components of drone 902. Power source 914 may implement may employ a high power battery low in weight, such as, but not limited to, lithium ion, lithium polymer, or lithium sulfide.

Any and all references to publications or other documents, including but not limited to, patents, patent applications, articles, webpages, books, etc., presented in the present application, are herein incorporated by reference in their entirety.

Example embodiments of the devices, systems and methods have been described herein. As noted elsewhere, these embodiments have been described for illustrative purposes only and are not limiting. Other embodiments are possible and are covered by the disclosure, which will be apparent from the teachings contained herein. Thus, the breadth and scope of the disclosure should not be limited by any of the above-described embodiments but should be defined only in accordance with claims supported by the present disclosure and their equivalents. Moreover, embodiments of the subject disclosure may include methods, systems and apparatuses which may further include any and all elements from any other disclosed methods, systems, and apparatuses, including any and all elements corresponding to target particle separation, focusing/concentration. In other words, elements from one or another disclosed embodiments may be interchangeable with elements from other disclosed embodiments. In addition, one or more features/elements of disclosed embodiments may be removed and still result in patentable subject matter (and thus, resulting in yet more embodiments of the subject disclosure). Correspondingly, some embodiments of the present disclosure may be patentably distinct from one and/or another reference by specifically lacking one or more elements/features. In other words, claims to certain embodiments may contain negative limitation to specifically exclude one or more elements/features resulting in embodiments which are patentably distinct from the prior art which include such features/elements.

What is claimed is:

1. An apparatus, comprising an IMU stack, said IMU stack comprising at least four magnetometers, wherein at least one magnetometer is in a different plane from at least three other magnetometers; an accelerometer and a gyroscope; and a camera, wherein said IMU stack obtains measurements for determining a location and/or orientation of said camera.

2. The apparatus of claim 1, wherein the IMU stack is implemented in a chip.

3. The apparatus of claim 1, wherein said IMU stack determines said location and/or orientation of said camera.

4. The apparatus of claim 3, further comprising a processing engine for determining said location and/or orientation of said camera.

5. The apparatus of claim 3, wherein each magnetometer is a 3D magnetometer.

6. The apparatus of claim 5, wherein said accelerometer is a 3D accelerometer.

7. The apparatus of claim 6, wherein said gyroscope is a 3D gyroscope.

8. The apparatus of claim 7, wherein said accelerometer and gyroscope are implemented as a MEMS (microelectromechanical system) IMU (inertial measurement unit).

9. The apparatus of claim 4, further comprising a communication device for communicating images from said camera with said location and/or orientation of said camera when said images were obtained.

10. The apparatus of claim 9, further comprising a storage for storing images from said camera with said location and/or orientation of said camera when said images were obtained.

11. The apparatus of claim 2, implemented with a plurality of dies, a first die comprising three magnetometers, a second die comprising a processor, and a third die comprising a magnetometer, the accelerometer and gyroscope, and a package, wherein said package contains said dies ordered in a plurality of stacked layers.

12. The apparatus of claim 4, comprising a plurality of cameras and a plurality of IMU stacks.

13. A drone, comprising the apparatus of claim 12, and further comprising an engine and propulsion system for supporting movement thereof.

14. A system, comprising the apparatus of claim 10 and a base station for receiving images from said camera with said location and/or orientation of said camera when said images were obtained.

15. The system of claim 14, wherein the apparatus is implemented in a drone.

16. A method, implemented with the system of claim 14, comprising:
determining a differential gradient between said out of plane magnetometer and said at least three other magnetometers;
calculating an azimuth according to said differential gradient;
fusing said azimuth, an orientation calculation from said gyroscope, and a tilt calculation from said accelerometer to determine a position of said camera; and
associating images taken when said camera is at said position with said position.

17. The method of claim 16 wherein said azimuth is an azimuth estimation from said magnetometers.

18. The method of claim 17, wherein the fusing is implemented using an optimal estimator such as a Kalman filter.
